(19) United States
(12) Patent Application Publication
(10) Pub. No.: US 2004/0261702 A1
(43) Pub. Date: Dec. 30, 2004

(54) Mechanically and thermodynamically stable amorphous carbon layers for temperature-sensitive surfaces

(76) Inventors: Udo Heinrich Grabowy, Enshircheu-Flawenderea (DE); Heinz Werner Busch, Thomasberg (DE)

Correspondence Address: John F Hoffman, Baker & Daniels, Suite 800, 111 East Wayne Street, Fort Wayne, IN, 46802, US

(21) Appl. No.: 10/493,683

(22) PCT Filed: Oct. 18, 2002
(86) PCT No.: PCT/EP02/11657

(30) Foreign Application Priority Data
Oct. 25, 2001 (DE) 101 52 055.7

(51) Int. Cl. C23C 16/00

(52) U.S. Cl. 118/715

(57) ABSTRACT

The invention relates to a method for depositing mechanically and thermodynamically stable amorphous carbon layers using a low-pressure plasma deposition method, especially a PE-CVD or combined PVD-/PE-CVD method. According to the invention, the average kinetic energy per deposited carbon atom is lower than 20 eV, preferably lower than 10 eV, and the ionic current density j is smaller than 0.2 mA/cm², and preferably smaller than 0.1 mA/cm².

The invention relates to a method for depositing mechanically and thermodynamically stable amorphous carbon layers, and to a system of layers with a carrier substrate and a layer of carbon deposited on it.

Using amorphous hydrocarbon layers (a-C:H), temperature-sensitive function components are equipped with a biocompatible, wear-resistant, and multifunctional surface.

According to the state of the art, amorphous carbon layers characterized by a homogeneous, dense, and stable network are produced by means of the low-pressure plasma deposition method, i.e., by, for example, a PVD, PE-CVD, or CVD method. A pre-requisite for coating very sensitive and complex components is the use of a coating method that allows to deposit layers at very low temperatures. The only suitable processes are PE-CVD and combined PVD/PE-CVD. The PVD, PE-CVD, and CVD methods are described in detail, for example, in the VDI lexicon “Elektronik und Mikroelektronik” [Electronics and Microelectronics], published by Dieter Sautter and Hans Weinerth, VDI-Verlag, 1990, pages 666 and 753. The disclosure content of this publication is included in this application in its entire extent.

In order to produce high quality layers, the indicated PVD, PVD/PE-CVD methods must include feeding energy into the layer. This process greatly increases the temperature of the substrate, especially the surface temperature. For example, it has been determined that during a carbon coating using the PE-CVD method, the temperature on the reverse side of a 500 μm-thick silicon substrate increased from the room temperature to 70°-90° C. within 90 seconds.

The temperature increase during the coating process depends on the energy and the current density of the ions coming onto the substrate, as well as on the material-specific properties of the substrate material, such as its heat capacity and heat conductivity.

The first task of the invention is to provide a coating method that avoids the disadvantages of the state of the art, and especially one that minimizes the temperature increase during the application of the layers.

According to the invention, during the coating process, this task is resolved by using a high-frequency generating plasma so that the ion energy is smaller than E=30 eV , and preferably smaller than E=20 eV, and the ionic current density is smaller than j=0.2 mA/cm², and preferably j=0.1 mA/cm².

The temperature increase within a time period of 90 s is calculated as:

ΔT=W*t/c*m)

ΔT=1° C.

Apart from the coating parameters, the choice of the substrate is determined by the temperature increase. Plastic materials have a lower heat conductivity and a smaller heat capacity than the silicon mentioned above. Thus, the expected temperature increase due to the coating process is accordingly higher in plastic materials. According to the state of the art, if we measure the temperature on a freely hanging thermal element directly in the ion beam, we obtain a temperature increase of ΔT=200° C., and a carbon ions energy level of E=90 eV; however, with the use of the invention, we measure a temperature increase of ΔT=20°-40° C. during the same process.

One of the measures of the characteristics of the stability of an amorphous hydrocarbon network is the mechanical properties of the layer system. The random covalent network (RCN) or the constraint model are suitable means of describing the mechanical properties (such as hardness and the elasticity module) of stable a-C:H layers. In this respect, we wish to refer to Phillips J. C. J. Non Cryst. Solids 51 (1979) 1355 and Thorpe M. F. J. Non Cryst. Solids 57 (1983) 355. This model describes the possibilities of deforming a network without any loss of energy (bending and tensile forces) in dependence on the mean coordination number of a covalent network. From these observations, there follows for carbon layers a mean coordination number of 2.4, below which a network can be deformed without any energy loss, and can thus create the so-called fully constrained network, FCN. For hydrocarbon networks, whose mean coordination numbers lie in this range, the ratio of the elasticity module and the hardness is approximately 6.

However, if the coordination number exceeds the number of the degrees of freedom, i.e., if the network is “over-constrained,” it does increase the mechanical stability, but it also decreases the thermodynamic stability, i.e., the layers become metastable and E/H<6. The same ratio applies to hydrogen-free a-C networks as it would to diamond or graphite (E/H=10).

Carbon layers that, in the sense of the RCN model, can be described as constrained, or even over-constrained, have so far always been deposited at energies above 30 eV. Layer systems deposited below these energies have a loose structure, are similar to thermally vapor-deposited layers or black carbon, and cannot be compared with a FCN system.

The inventors have succeeded in using the method designed by their invention to deposit, with very low particle energies (around 10 eV per layer-forming particle), an FCN a=C:H system, whose E/H ratio is around 6; i.e., the amorphous layer system has a compact structure and is mechanically very stable. It has a hardness of about 10 Gpa and, compared with steel (4-7 Gpa), is extremely mechanically resistant. In its elastic properties, an E module of 60 Gpa is achieved. Thus, this carbon layer is ideally suitable for coating highly flexible plastic material surfaces.

In order to produce the layers as designed by the invention, a high frequency-generated directed plasma with a high ionization degree (about 25%) was produced and extracted into a process chamber. Acetylene (C₂H₂) with a working pressure of around 2*10⁻³ mbar was used as the process gas. The high-frequency performance was inductively coupled and was between 150 and 300 Watts.

The layers as designed by the invention were deposited in space geometrically shielded from the above-described primary plasma, in which secondary plasma is generated.

This secondary plasma falls within the described parameters, i.e. 10 eV per layer-forming particle, which results in the indicated properties of the layers produced according to the invention, i.e., a hardness of approximately 10 Gpa and an E module of approximately 60 Gpa.

Using this deposition method, we have succeeded, for the first time, in depositing a fully constrained network at energies lying significantly below the otherwise usual penetration energy of 30 eV, which is normally the pre-requisite for a substantial compaction of an amorphous network. The C₂H₂⁺ ions used for the coating have an average kinetic energy in a range that falls below 20 eV; i.e., the average kinetic energy per deposited C atom is at most around 10 eV.

Only low-energy ions reach the surface to be coated, which is why the thermal stress exerted upon the component to be coated during this PE-CVD process is negligible. In addition, the surface temperature increase caused by the electrons found in the quasi-neutral plasma jet is also greatly reduced by this arrangement. Furthermore, the dissociation energy of the C₂H₂⁺ ions that is being released during the formation of the layer further supports the formation of a dense, amorphous network with particles that have low kinetic energies. As shown by a structural examination of these layer systems, starting from a layer thickness as small as of 5 nm, we obtain an atomically dense amorphous network.

As regards the application of these layer systems, besides the mechanical and biocompatibility properties, it is above all the optical properties that are of great interest.

The inventors have succeeded, for the first time, in producing layers deposited at very small kinetic energies with an optical gap of 2.2 eV. These layers are characterized by a very low absorption in the visible wavelength range. For layer thicknesses of 5 nm, the optical transmission in the wavelength range from 900 to 400 nm is over 80%. For layers of 8 times this thickness (40 nm), the transmission is only reduced to 60%. With a suitable thickness, the layers produced by the described method can be characterized as being transparent.

The layers described here are especially interesting for the coating of temperature-sensitive components, in which the surface to volume ratio is high. Besides the fields of micro- and nano-mechanics, electronics, and sensor technology, these layers are widely applied in medicine, because they can be deposited on any material while retaining the above-described properties.

These carbon layers are relatively elastic and, for example, with regard to medical applications, have the advantage that they can follow the movements of an implant without any risk that cracks will form or that the layer would even peel off. This combination of hardness and elasticity, the very low coating temperature, and the biocompatibility, which was proven in the first experiments, opens new possibilities of application in medical technology.

In a biological system, adsorption of proteins takes place immediately after contact with the surface of an implant. The adsorption of proteins can cause a cell adsorption, which can result in the formation of thick and physiologically dubious layers. This process represents an especially serious problem in the case of implants that have contact with blood. Depending on the specific requirements, various substances can be used as the material for an implant. Amorphous carbon layers generally behave neutrally and manifest minute adhesion forces. This causes a reduction in the adsorption of biological substances, and thus the duration of the coated implant's stay in the body can be extended; moreover, the implant is generally better accepted by the body.

Another task of the invention is to indicate a layer system to be used in the fields of biology, analytical biology, medicine, and pharmaceutical industry, which isolates a substrate, i.e., a carrier from the environment using a diffusion barrier. The inventors found that layer systems with a carbon layer deposited on the carrier substance suit this purpose very well. These layers may, but need not be deposited according to the methods as designed by the invention and characterized in claim 1. The only imperative feature of the layer is that it isolates the substrate from the environment as a diffusion barrier. This is especially important, for example, in cell culture dishes, Petri dishes, multi-wave plates, micro titration plates, glass containers, and in catheters that are used in the fields of biology, analytical biology, medicine, or in the pharmaceutical industry. In the field of analytical biology, when one uses plastic material substrates as carrier materials, molecules of minute mass are released from the used plastic material substrate. These molecules limit the accuracy of measurement during an analysis, especially if containers made of plastic materials are used. This problem can be resolved using an amorphous carbon layer as the diffusion barrier.

Another important field of application of the layer system as designed by the invention, in which an amorphous carbon layer is deposited on the carrier substrate, is the coating of cell culture dishes. In cell culture dishes, there is also interaction between the substrate and the cells brought into the dish, which can influence the development of cells. Surprisingly, it has now been found that in cell culture dishes in which the substrate material has been coated with amorphous carbon layer, the interaction between the substrate and the cells is substantially reduced.

Another possible use for the amorphous carbon layers is the coating of substrates onto which an active substance, for example, a drug, is brought. Due to chemical bonding mechanisms, active substances of a drug cannot stick to a metal surface for too long. Here, a biocompatible in-between layer must be used. The biocompatible in-between layer must have both a good adhesion to the substrate, for example a metal carrier, and, simultaneously, provide the possibility of a good connection with the medically active substance. This is made possible by amorphous carbon layers deposited on a carrier substrate.

As has been pointed out earlier, the aforementioned application of amorphous carbon layers onto carrier substrates is also possible in cases where the amorphous carbon layer has not been deposited according to one of the methods indicated in claim 1. As a principle, the method of depositing the carbon layer for such applications is unimportant. The only pre-requisite is that the substrate must not be destroyed or changed during the coating process.

In the following text, we will provide some examples of the application of the carbon as designed according to the invention in the field of medicine.

### DESIGN EXAMPLE 1

### Catheter

The biggest complication when using a catheter, for example, in dialysis or in cardiology, is bacteria. Bacteria are especially likely to be deposited on catheters that have been in contact with the human body over a longer period of time. From the implant, these bacteria can then penetrate the body and cause persisting inflammations. The new DLC coating allows one to reduce the adhesion of bacteria to temperature-sensitive catheters.

### DESIGN EXAMPLE 2

### Intraocular Lenses

Intraocular lenses are implanted in the patient's eye during the treatment of a gray lenticular cataract as a substitute for the natural cataractous lense. Possible complications include increased bacteria infestation of the implant and excessive formation of epithelium cells (secondary cataract). First experiments with a special coating made of amorphous carbon on acryl and PMMA lenses have shown no bacteria infestation.

Another advantage of the invention consists in the optical properties of the DLC layers, which contain a high content of hydrogen. Due to the large optical gap, these layers have a high transparence for visible light, while at a layer thickness as small as 10 nm, a strong level of UV absorption is already observed. Due to the temperature sensitivity of the

Intraocular lenses that are being used, the coating temperature must be under 50° C.

### DESIGN EXAMPLE 3

### Vascular implants

Vascular implants called stents are applied in cases of seriously narrowed blood vessels. In the coronary area, in more than 30% of all cases, a new stenosis occurs. A biocompatible coating of the stents can substantially improve the situation. The role of the biocompatible coating is to prevent a diffusion of metal ions into the body. In addition, amorphous carbon layers suffer from a much lower adhesion of thrombocytes, which substantially reduces the risk of the development of thrombosis after the implantation of the stent.

Due to their high elasticity, the DLC layers deposited at low temperatures are very suitable for such an application, which is exposed to high stress by the continuing movement in the blood vessel. They are able to follow the movements much better than the layers made according to the current state of the art.

### DESIGN EXAMPLE 4

### Brachytherapy

The use of ionized radiation to suppress the growth of undesirable cells (tumor tissue) is well known from cancer therapy. During brachytherapy, sources of radiation are implanted inside the patient's body for a certain period of time. In this process, high doses of radiation—a multiple of the lethal dose—are focused on the target space. Closed sources of radiation are usually used, and their activity is not distributed within the body. However, due to their minute reach, miniaturized implants, which emit ionizing radiation, can be encased only with great difficulties, because the casing itself would absorb a substantial part of the radiation.

A possible solution is to encase the source of radiation using a thin, biocompatible, diffusion-tight carbon layer as designed by the invention.

The activation of the implants can be triggered using a high-flux nuclear reactor.

1. Method for the deposition of mechanically and thermodynamically stable amorphous carbon layers using a low-pressure plasma generation method, especially a PE-CVD or a combined PVD/PE-CVD process, characterized in that the average kinetic energy per deposited carbon atom is smaller than 20 eV, and preferably smaller than 10 eV, and in that the ionic current density j is smaller than 0.2 mA/cm², and preferably smaller than 0.1 mA/cm².

2. Method according to claim 1, characterized in that C2H2+ ions with an average kinetic energy<40 eV, and especially those of 20 eV, are used as the ions.

3. Layer system with a carrier substrate and a carbon layer deposited on a carrier substrate, especially one that is produced by the method according to claim 1.

4. Layer system according to claim 3, characterized in that the deposited carbon layer has a hardness of more than 7.5 Gpa, and preferably more than 10 Gpa.

5. Layer system according to claim 3, characterized in that the layer has an E module of more than 40 Gpa, and preferably more than 60 Gpa.

6. Layer system according to claim 3, characterized in that the carrier substrate of the layer system is a plastic material.

7. Layer system according to claim 3, characterized in that the carrier substrate of the layer system is a glass material.

8. Catheter to be used in dialysis, and/or cardiology, characterized in that the catheter is coated with a carbon layer, especially that produced by a method according to claim 1.

9. Intraocular lense, characterized in that the intraocular lense comprises a carbon layer produced by a method according to claim 1.

10. Vascular implant, characterized in that the vascular implant comprises a carbon layer produced by a method according to claim 1.

11. Vascular implant according to claim 10, characterized in that the vascular implant is an implant that emits ionizing radiation.

12. Cell culture dish to be used especially in biology, analytical biology, medicine, and/or the pharmaceutical industry, characterized in that the cell culture dish comprises an amorphous carbon layer.

13. Cell culture dish to be used in biology, analytical biology, medicine, and/or the pharmaceutical, characterized in that the cell culture dish comprises a carbon layer produced by a method according to claim 1.

14. Petri dish to be used especially in biology, analytical biology, medicine, and/or the pharmaceutical industry, characterized in that the cell culture dish comprises an amorphous carbon layer.

15. Petri dish to be used in biology, analytical biology, medicine, and/or the pharmaceutical industry according to claim 14, characterized in that the cell culture dish comprises a carbon layer produced by a method according to claim 1.

16. Multi-wave plates to be used especially in biology, analytical biology, medicine, and/or the pharmaceutical industry, characterized in that the multi-wave plate comprises an amorphous carbon layer.

17. Multi-wave plates to be used in biology, analytical biology, medicine, and/or the pharmaceutical industry according to claim 16, characterized in that the multi-wave plate comprises a carbon layer produced by a method according to claim 1.

18. Micro titration plates to be used especially in biology, analytical biology, medicine, and/or the pharmaceutical industry, characterized in that the micro titration plate comprises an amorphous carbon layer.

19. Micro titration plates to be used in biology, analytical biology, medicine, and/or the pharmaceutical industry according to claim 18, characterized in that the multi-wave plate comprises a carbon layer produced by a method according to claim 1.

20. Glass containers to be used especially in biology, analytical biology, medicine, and/or the pharmaceutical industry, characterized in that the glass container comprises an amorphous carbon layer.

21. Glass containers to be used in biology, analytical biology, medicine, and/or the pharmaceutical industry according to claim 20, characterized in that the glass container comprises a carbon layer produced by a method according to claim 1.
